(19) United States
(12) Patent Application Publication
(10) Pub. No.: US 2026/0309751 A1
(43) Pub. Date: Oct. 8, 2026

(54) OVERHEAD POWERLINE DETECTION

(71) Applicant: KOMATSU AUSTRALIA PTY LTD, Fairfield East, New South Wales (AU)

(72) Inventors: Benjamin Henrik Vita TERRACINI, Fairfield East, New South Wales (AU); Hansel REBELLO, Fairfield East, New South Wales (AU)

(73) Assignee: KOMATSU AUSTRALIA PTY LTD, Fairfield East, New South Wales (AU)

(21) Appl. No.: 19/481,699

(22) PCT Filed: Nov. 29, 2024
(86) PCT No.: PCT/AU2024/051283

§ 371 Date: Nov. 5, 2025

(30) Foreign Application Priority Data
Dec. 5, 2023 (AU) 2023903934

(51) Int. Cl. G01R 15/14; G01R 19/165; G01S 13/08; G01S 17/08

(52) U.S. Cl. CPC G01R 15/14; G01R 19/16576; G01S 13/08; G01S 17/08

(57) ABSTRACT

A system and method for detecting an overhead powerline (203). The system 200 comprises a first sensor (205) configured to detect (110) a field (207) generated by the overhead powerline (203), a second sensor (209) configured to detect (120) a relative position (210), including a distance (211), between the overhead powerline (203) and the second sensor (209); and a controller (213) including one or more processors. The controller (213) is configured to receive (130) first sensor data (217) from the first sensor (205) and second sensor data (219) from the second sensor (209); estimate (140) a live voltage value (221) of the overhead powerline (203) based on the first sensor data (217) and the second sensor data (219); determine (150) one or more threshold safety distances (223) based on the live voltage value (221); and determine (160) the distance (215) of the overhead powerline (203) to the system (200) based on the second sensor data (209). In response to the determined distance (215) is within, or approaches, the one or more threshold safety distances (223), generate (170) a warning signal (225).

### TECHNICAL FIELD

This disclosure relates to systems and methods that comprises one or more sensors for detecting overhead powerline to avoid accidents. The disclosure may, in some examples, be applied to engineering vehicles.

### BACKGROUND

Overhead powerline accidents represent a significant safety concern, as evidenced by their prevalence in various regions. For example, in Australia, EnergySafe Victoria reported 141 overhead powerline incidents (e.g., collisions) in 2021. Overhead powerline accidents are particularly common for work sites where engineering vehicles are operational. The consequences of those overhead powerline accidents are often severe, including serious injuries or even death of individuals, damage of equipment and fatalities and delay of working progress to restore damage caused by the accidents.

Some detection systems utilise cameras or infrared distance sensors to detect objects in the environment. However, such detection systems are unable to provide crucial details, such as the voltage of the powerline and are subject to environment conditions (e.g., weather and visibility conditions). Moreover, those detection systems cannot effectively differentiate overhead powerlines from other obstacles in the environment.

Systems equipped with one or more sensors are useful to remotely detect the overhead powerline to avoid the overhead powerline accidents. These systems using sensors enable comprehensive monitoring and detection capabilities, enhancing safety measures in environments where overhead powerlines are present.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

Any discussion of documents, acts, materials, devices, articles or the like which has been included in the present specification is not to be taken as an admission that any or all of these matters form part of the prior art base or were common general knowledge in the field relevant to the present disclosure as it existed before the priority date of each of the appended claims.

### SUMMARY

There is provided a system for detecting an overhead powerline, the system comprising: a first sensor configured to detect a field generated by the overhead powerline; a second sensor configured to detect a relative position, including a distance, between the overhead powerline and the second sensor; and a controller including one or more processors configured to: receive first sensor data from the first sensor and second sensor data from the second sensor; estimate a live voltage value of the overhead powerline based on the first sensor data and the second sensor data; determine one or more threshold safety distances based on the live voltage value; determine the distance of the overhead powerline to the system based on the second sensor data; and in response to the determined distance is within, or approaches, the one or more threshold safety distances, generate a warning signal.

In some embodiments, the controller is configured to generate an emergency warning signal in response to the first sensor data indicating the field being greater than or equal to the specified emergency threshold value.

In some embodiments, the system further comprises a filtering system configured to extract, from the first sensor data, signals in a specified frequency band corresponding to the field generated at the overhead powerline by alternating current, wherein the signals in the specified frequency band are indicative of live alternating current in the overhead powerline.

In some embodiments, the determined one or more threshold safety distances increase in response to an increase in the live voltage value.

In some embodiments, the controller is configured to estimate the live voltage value based on a condition that the first sensor data indicating the field is greater than or equal to a specified minimum threshold value.

In some embodiments, the second sensor comprises a Light Detection and Ranging system.

In some embodiments, the second sensor comprises a camera sensor, wherein the camera sensor is configured to capture visual data of one or more objects in a surrounding environment.

In some embodiments, the controller is further configured to: process the visual data of the one or more objects; and determine the one or more objects including the overhead powerline.

In some embodiments, determining the distance of the overhead powerline to the system comprises data fusion of the visual data from the camera sensor and distance data received from the LiDAR sensor.

In some embodiments, the system is associated with an engineering vehicle comprising an arm assembly, wherein at least one of the first sensor or the second sensor are provided at respective sensor locations on the arm assembly.

In some embodiments, the one or more threshold safety distances are further based on a size and/or configuration of one or more components of the engineering vehicle associated with the system.

In some embodiments, the size and/or configuration includes one or more of: an overall size and/or shape of the engineering vehicle; a length and/or height of a boom of the engineering vehicle; a length and/or height of an arm of the arm assembly; a reach of the engineering vehicle; a digging height of the engineering vehicle; a dumping height of the engineering vehicle; a swing radius of the boom and/or the arm of the arm assembly; a swing radius of an attachment of the engineering vehicle, wherein the attachment is attached to a distal end of the arm assembly; one or more boom swing angles of the engineering vehicle; and a configuration, size and/or position of a cabin of the engineering vehicle.

In some embodiments, based on the second sensor data, the controller is further configured to calculate any one or more of: one or more spatial boundaries in the surrounding environment; and/or one or more movements of the overhead powerline.

In some embodiments, the respective sensor locations include any one or more of: a location near a first joint of the boom and the arm of the engineering vehicle; a location near a second joint of the arm and the attachment of the engineering vehicle; and/or a location on the attachment of the engineering vehicle.

In some embodiments, the field is any one of an electric field, a magnetic field or an electromagnetic field.

In some embodiments, the second sensor comprises a millimetre wave radar.

In some embodiments, the system further comprises a third sensor configured to detect a proximity between the third sensor and the one or more objects in the surrounding environment, the objects including the overhead powerline, wherein in response to the detected proximity is at or below a safety margin, the controller is further configured to generate a further alarm to warn of a risk of collision between the one or more object and the engineering vehicle.

In some embodiments, the relative position further includes a direction of the overhead powerline.

In some embodiments, detecting the overhead powerline further comprises determining a shape extracted from the second sensor data that corresponds to one or more of a length of the overhead powerline, a sag of the overhead powerline, and/or a geometry of the overhead powerline.

In some embodiments, the system further comprises a monitor panel configured to display one or more indications including any one or more of: An indication of the voltage value of the overhead powerline; an indication of a second distance between the arm of the engineering vehicle and the overhead powerline; an indication of a third distance between the boom of the engineering vehicle and the overhead powerline; an indication of a fourth distance between the attachment of the engineering vehicle and the overhead powerline; an indication of one or more directions of the overhead powerline and/or one or more directions of the one or more objects in the surrounding environment; an indication of the shape of the overhead powerline; an indication of the movement of the overhead powerline; an indication of the real-time or near-real-time visual data of the surrounding environment; an indication of a point cloud of the surrounding environment; and/or an indication of a visual warning signal.

In some embodiments, the system further comprising a warning system, wherein the warning system comprises any one or more of: one or more warning lights including one or more threshold lights and an emergency warning light configured to present the emergency warning signal; one or more alarm devices; and one or more emergency shut-off mechanisms configured to stop one or more actuators of the engineering vehicle.

In some embodiments, the filtering system comprises any one or more of: an analog filtering system including a hardware bandpass filter; and/or a digital filtering system including a Fast Fourier Transform (FFT) filter.

There is also provided a method for detecting an overhead powerline by a system comprising a first sensor, a second sensor and a controller including one or more processors, wherein the method comprises: detecting, by a first sensor, a field generated by the overhead powerline; detecting, by a second sensor, a relative position, including a distance, between the overhead powerline and the second sensor; receiving, by a controller including one or more processors, first sensing data from the first sensor and second sensing data from the second sensor; estimating, by the controller, a live voltage value of the overhead powerline using the first sensing data and the second sensing data; determining, by the controller, one or more threshold safety distances based on the live voltage value; and determining, by the controller, the distance of the overhead powerline to the system based on the second sensor data, in response to the determined distance is within, or approaches, the one or more threshold safety distances, generate a warning signal.

There is further provided a computer program comprising machine-readable instructions that, when executed by a computer, causes the computer to perform any of the methods described herein.

### BRIEF DESCRIPTION OF DRAWINGS

Some embodiments are described herein below with reference to the accompanying drawings, wherein:

FIG. 1 is a flow diagram of a process for detecting an overhead powerline;

FIG. 2 is a schematic diagram of an example system comprising a first sensor, a second sensor and a controller for implementing the method illustrated in FIG. 1;

FIG. 3 is a schematic diagram of an example of the first sensor implementing capacitive sensing;

FIG. 4 illustrates measurement results for signals acquired from a 415V transmission powerline;

FIG. 5a is a schematic diagram of an example of a radar sensor of the second sensor;

FIG. 5b is a schematic diagram of an example of the controller;

FIG. 5c illustrates test results for detected status and distances when aiming the second sensor (such as a radar system) from a distance of about 1 m to a powerline;

FIG. 5d is a schematic diagram of an example of a Light Detection and Ranging (LiDAR) sensor of the second sensor;

FIG. 6a illustrates an exemplary user interface displayed on a monitor panel of the system illustrated in FIG. 2 when implementing the method shown in FIG. 1.

FIG. 6b is a block diagram illustrating various types of indications in relation to detection results that can be displayed on the monitor panel;

FIG. 7 is a block diagram illustrating different types of components of an example warning system;

FIG. 8a illustrates a front view of an example of an engineering vehicle (such as an excavator) using the powerline detection system;

FIG. 8b illustrates a top view of the example of the engineering vehicle of FIG. 8a;

FIG. 8c is a front view of the engineering vehicle of FIG. 8a.

### DESCRIPTION OF EMBODIMENTS

### Overview

Systems equipped with sensors provide efficient ways to remotely detect overhead powerlines and/or other objects in the surrounding area of an engineering vehicle. An engineering vehicle often operates on a work site and can perform a range of tasks that typically occupy a considerably large space, such as excavation, material loading, handling or moving, backfilling and demolition. The system equipped with sensors is often attached to the engineering vehicle, which can be but not limited to the following types: an excavator, a backhoe, an electric rope shovel and a dump truck. When operating, the system processes data received from the sensors and determines whether there is a hazard, such as a collision between a part of the engineering vehicle (e.g., a bucket of an excavator) and a surrounding object (e.g., an overhead powerline). Upon detecting the overhead powerline, the powerline detection system generates warning signals, alerting the vehicle operator of the potential hazard.

Some powerline detection systems implement one or more electric field sensors to detect the alternating current (AC) of the powerline. However, a limitation of these systems is their inability to discern the direction of the AC powerlines, detect direct current (DC) powerlines, or identify other environmental obstacles.

Disclosed herein are methods, systems and computer programs for detecting an overhead powerline that ameliorate one or more of the aforementioned drawbacks, or any other drawbacks of the prior art, or that at least provide a useful alternative.

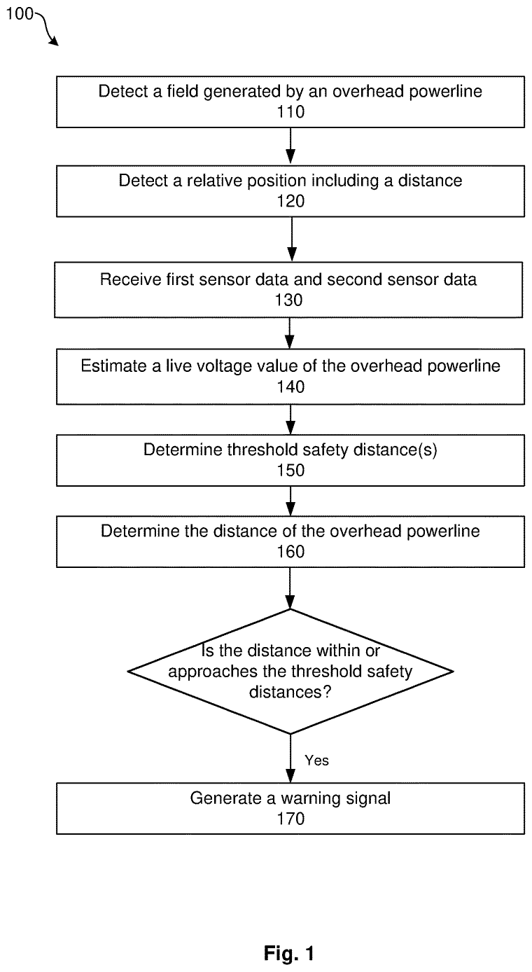

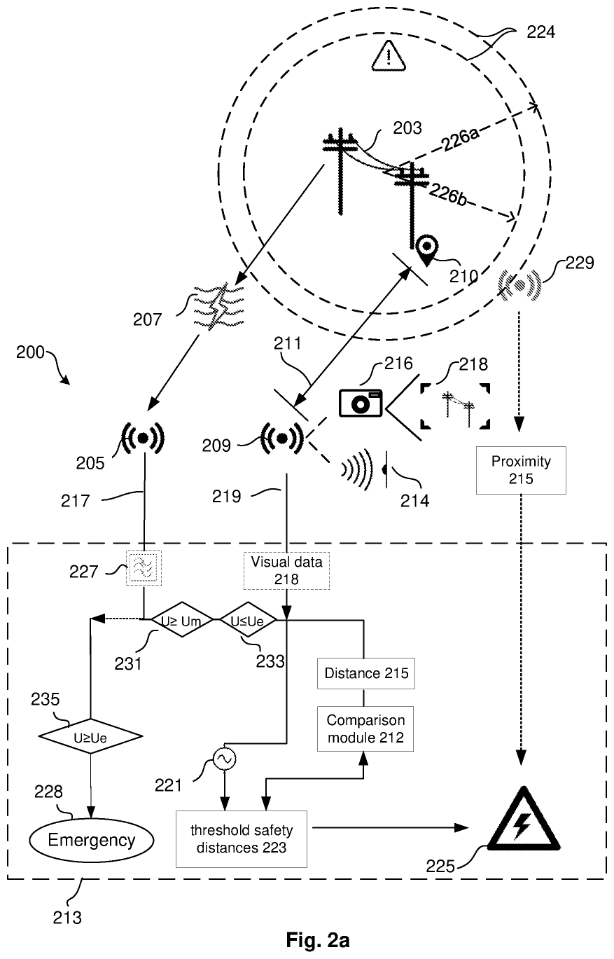

FIG. 1 illustrates a method 100 for detecting an overhead powerline 203. FIG. 2 illustrates a system 200 for implementing the method 100, comprising a first sensor 205 (to detect fields generated by overhead powerlines), a second sensor 209 (to detect relative position of the powerline) and a controller 213 connected to the first sensor 205 and the second sensor 209. The first sensor 205 and the second sensor 209 may either co-located at the same position on the engineering vehicle or strategically set at different positions on the engineering vehicle for optimal functionality and coverage.

The method 100 comprises detecting 110, by a first sensor 205, a field 207 generated by an overhead powerline 203. The field 207, which may be an electric field, a magnetic field, or an electromagnetic field, is generated by alternating current (AC) or direct current (DC) transmitted by the overhead powerline 203. The applicable type of the first sensor 205 depends on the field 207 to be detected. For example, in some embodiments, the first sensor 205 is a capacitive sensor configured to measure the electric field generated by the overhead powerline 203.

The method 100 also comprises detecting 120, by a second sensor 209, a relative position 210 of the overhead powerline 203. The relative position 210 includes at least a distance 211 between the overhead powerline 203 and the second sensor 209. The second sensor 209 includes any one or more of but not limited to a radar sensor, a LiDAR (laser imaging detection and ranging) sensor 214 or a camera sensor 216. Approaches for detecting 120 the relative position 210 are tailored to the type of the second sensor 209 employed. For example, if the second sensor 209 comprises a radar sensor or a LiDAR sensor 214, detecting 120 the relative position 210 involves receiving and analysing the transmitted electromagnetic signals (for the radar sensor) or laser light (for the LiDAR sensor) reflected by the physical object of the overhead powerline 203. If the second sensor 209 comprises a camera sensor 216, detecting 120 the relative position 210 includes image recognition, tracking and processing.

It should be understood that the term “a sensor” does not limit the number of physical sensor components for practical applications to a singular unit. Broadly, “a sensor” refers to a sensing system that can include one or more sensor components. Terms such as “a first sensor”, “a second sensor”, “a third sensor”, “a radar sensor”, “a camera sensor” or “a LiDAR sensor” accommodates various configurations, from a single sensor unit to a complex array of sensors, each contributing to the collective functionality of the overall sensing system. For example, the second sensor 209 may include a combination of a LiDAR sensor 214 and a camera sensor 216.

Typically, the term “distance” should be understood as the measurement of spatial separation from a designated point A to the closest point on an object of interest. In the context of the disclosure, the distance 211 between the overhead powerline 203 and the second sensor 209 may be the measurement of spatial separation from the centroid of the second sensor 209 to a point on the overhead powerline 203, which is closest to the centroid.

The method 100 further comprises receiving 130, by the controller 213 including one or more processors, first sensor data 217 from the first sensor 205 and second sensor data 219 from the second sensor 209. In some embodiments, the first sensor data 217 includes signals within a particular frequency band (e.g., 50 to 60 Hz), where the overhead powerline 203 transmits AC. The field 217 may be a parameter indicating the strength of the field 207, such as voltage, electric field strength, magnetic field strength and power. The second sensor data 219 includes information regarding the relative position 210 including the distance 211. The controller may receive sensing data 217, 219 from the first and second sensors 205, 209 through either wired data transmission components, such as High-Definition Multimedia Interface (HDMI), Universal Serial Bus (USB) or other types of cables, and wireless data transmission using radio frequency, such as Wi-Fi, Bluetooth or Cellular Networks.

Upon receiving the first sensor data 217 and the second sensor data 219, the method 100 further comprises estimating 140, by the controller 213, a live voltage value 221 of the overhead powerline 203 based on the first sensor data 217 and the second sensor data 219. In some embodiments where the first sensor 205 comprises a capacitive sensor, the live voltage value 221 can be calculated based on the measured capacitances and voltage at the spatial point where the measurement is carried out. For example, the live voltage value 221 can be calculated by implementing the methods in a publication “Walczak, Krzysztof, and Wojciech Sikorski. “Non-contact high voltage measurement in the online partial discharge monitoring system.” Energies 14.18 (2021): 5777” (“Walczak & Sikorski” hereinafter).

In some embodiments where the first sensor 205 and the second sensor 209 are co-located, the live voltage value 221 of the overhead powerline 203 can also be calculated based on an intensity of the field 207 measured at the first sensor 205 and the distance 211 detected by the second sensor 209. This approach is based on the principle established in Walczak & Sikorski that the intensity of the field is approximately inversely proportional to the distance 211 between the overhead powerline and the first sensor 205. The live voltage value 221 allows for precise control over the calibration and configuration of the system 200.

The method 100 further comprises determining 150, by the controller 213, one or more threshold safety distances 223 based on the estimated live voltage value 221. The live voltage value 221 determines (or can be used, at least in part, to specify) a danger zone 224 surrounding the overhead powerline 203 indicating an area of high risk, where an electrical arc may exist. Such electrical art may cause undesired injury to individuals or damage to equipment even without any direct contact with the powerline 203.

In some embodiments, the one or more threshold safety distances 223 are specified (e.g. pre-determined) for different live voltage values 221 and are pre-stored as a reference dataset (e.g., a lookup table for threshold safety distances). The process of determining 150 the one or more threshold safety distances 223 may include retrieving the appropriate one or more threshold safety distances 223 from the lookup table based on the estimated live voltage value 221.

In some embodiments, the controller 213 generates the one or more threshold safety distances 223 by performing one or more calculations using the live voltage value 221. The one or more calculations may take into account additional factors, including environmental parameters (e.g., humidity and weather conditions) and characteristics of the equipment (e.g., sensitivity of devices and strength of arc flash protection).

In one simplified example, one or more fixed threshold safety distances 223 are applied across a range of live voltage values 221. This approach can expedite the determination process 150 and is useful in some scenarios where rapid response is significant.

Generally, the one or more threshold safety distances 223 increase in response to an increase in the live voltage value 221. In some embodiments, the one or more threshold safety distances 223 may comprise a threshold radius 226 extending from a central part (e.g., a geometric center) of the overhead powerline 203, where the area within a virtual sphere having the threshold radius 226 is considered as the danger zone 224.

The method 100 further comprises determining 160, by the controller 213, the distance 211 of the overhead powerline 203 to the system 200 based on the second sensor data 219. The distance 215 may be determined based on the distance 211 between the overhead powerline 203 and the location of the second sensor 209 on the engineering vehicle. In some embodiments, the distance 211 and the distance 215 may be the same if an integrated system is implemented.

In response to the determined distance 215 is within, or approaches, the one or more threshold safety distances 223, the method 100 further comprises generating 170, a warning signal 225 to remind the operator of the engineering vehicle of the potential risks associated with overhead powerline accidents. In various embodiments, the warning signal 225 is in the form of light, sound (i.e., audible) or visual warning output displayed on a monitor panel of the engineering vehicle. The warning signal 225 can also indicate different levels of hazard based on the proximity between the engineering vehicle and the overhead powerline 203.

Advantageously, the system 200 synergises different types of sensors, i.e., the first sensor 205 configured to detect the field 207 and the second sensor 209 configured to detect the relative position 210. The synergy provides efficient powerline detection, as well as hazard prediction and prevention. Specifically, by concurrently processing the different types of sensing data (i.e., the first sensor data 217 and the second sensor data 219), the system 200 comprehensively estimates different characteristics of the overhead powerline 203, including the relative position 210, the live voltage value 221 and other characteristics such as shape and movement of the overhead powerline 203. The system 200 improves the overall performance of powerline detection and hazard prediction and prevention in terms of accuracy, robustness in dynamic environments (e.g., weather and visibility conditions) and detection range (e.g., providing small or negligible blind spots). Moreover, the use of the first and second sensors may enhance accuracy in determining that (suspected) overhead lines are indeed live powerlines.

The system 200 enhances the predictive accuracy of potential risks, enhance the situational awareness, protects the equipment and operators from overhead powerline accidents, reduces downtime and related costs and improves operational safety protocols. Therefore, the system 200 offers a beneficial solution for mitigating hazards of overhead powerline accidents.

### First Sensor Configured to Detect a Field

As described above, at step 110, the first sensor 205 detects a field 207 generated by the overhead powerline 203. For overhead powerline 203 transmitting alternating current (AC), an electromagnetic field 207 is generated from the AC, of which the current and voltage periodically change. Typically, the waveform of AC is a sine wave having a peak voltage Uₚₑₐₖ and frequency f. For overhead powerline 203 transmitting direct current (DC) having constant direction, current and voltage, the DC overhead powerline generates an electric field and a magnetic field (which is generated from the movement of electric charge). In general, for DC overhead powerlines, the intensity of the generated electric field or magnetic field decreases in response to the increase in the distance from a measured point to the powerline 203.

The type of the first sensor 205 may vary depending on the type of field (e.g., electric, magnetic or electromagnetic field) to be detected. For example, the first sensor 205 can be but not limited to the following types: an electric field transducer, a magnetic transducer, an electromagnetic field (EMF) meter, a Radio Frequency (RF) field strength meter and a capacitive sensor.

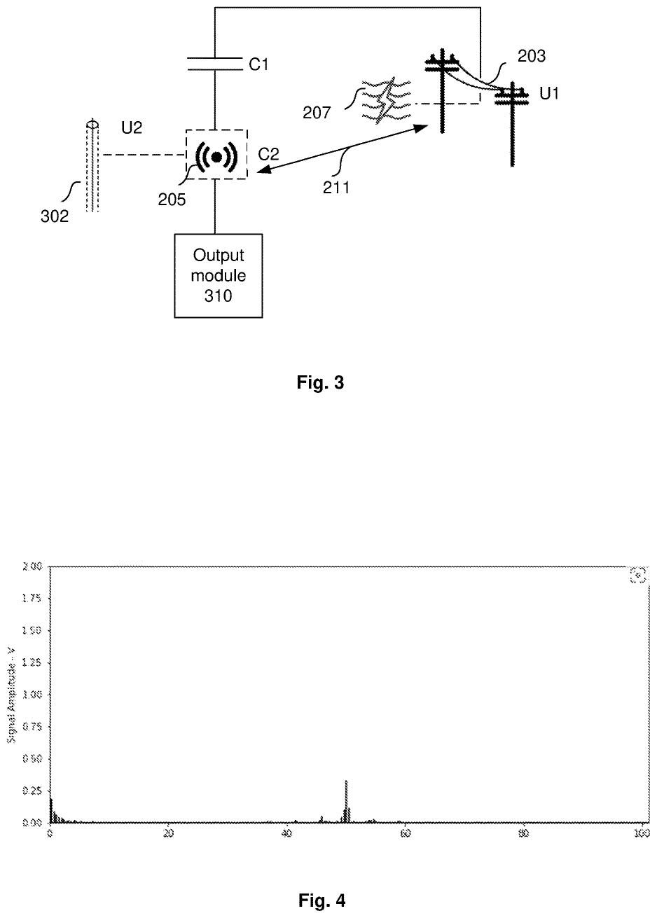

FIG. 3 shows the schematic diagram of an example of the first sensor 205 implementing capacitive sensing using a capacitive probe 302, which can measure induced voltages in a conductor when placed in an electric field 207. As discussed in Walczak & Sikorski, despite the influence of the interference, the live voltage U₁ at the overhead powerline 203 is proportional to the voltage U₂ measured with the capacitive probe 302, that is,

$${U}_{1} = v \cdot {U}_{2} , \qquad ( Equation 1 )$$

where v is a voltage ratio. The voltage ratio v may be obtained from the coupling capacitance C₁ between the capacitive probe 302 and the overhead powerline 203, the resultant capacitance C₂ of the first sensor 205 and the resistance Rₛ of the voltmeter or oscilloscope, which can be obtained from laboratory and provided in a specification of the capacitive probe 302. That is,

$$v = \frac{{C}_{1} + {C}_{2}}{{C}_{1}} - j \frac{1}{{fC}_{1} {R}_{s}} , \qquad ( Equation 2 )$$

where f is the frequency of AC.

As verified in Walczak & Sikorski, the voltage U₂ measured with the capacitive probe 302 is also approximately inversely proportional to the distance r between the capacitive probe 302 and the overhead powerline 203. That is,

$${U}_{2} = \frac{A}{r} , \qquad ( Equation 3 )$$

where A is a function parameter that is a constant for a specific live voltage value 221 (i.e., U₁) of the overhead powerline 203.

Signals obtained by the first sensor 205 (e.g., such as voltage signals obtained by the capacitive probe 302) may be processed in the output module 310. The output module 310 may comprise analog components such as one or more amplifiers, one or more filters, one or more internal power supplies and an analog/digital converter. The output module 310 may further transmit the processed digital signal to the controller 213 for further processing (e.g., for estimating 140 a live voltage value 221) via either wired data transmission components (e.g., USB, HDMI or other types of cables) or wireless data transmission using radio frequency (e.g., Wi-Fi, Bluetooth or Cellular Networks).

In most countries, the frequency f of the AC overhead powerline 203 is 50 Hz or 60 Hz. As a result, to detect the field 207 of the AC overhead powerline 203, the system 200 may further comprise a filtering system 227 configured to extract, from the first sensor data 217, signals in a specified frequency band corresponding to the field 207 generated at the overhead powerline 203 by AC.

The signals in the specified frequency band are indicative of live alternating current in the overhead powerline 203, for example, around 50 Hz or 60 Hz, depending on the application scenario. In some examples, the filtering system 227 is configured to extract signals in a frequency band of about 45 Hz to about 55 Hz to detect AC overhead powerlines having a frequency of 50 Hz. In one example, the filtering system 227 is configured to extract signals at 50 Hz. In alternative examples, the filtering system 227 is configured to extract signals in a frequency band of about 55 Hz to about 65 Hz to detect AC overhead powerlines having a frequency of 60 Hz. In one example, the filtering system 227 is configured to extract signals at 60 Hz. The filtering system 227 may be further configured to filter the noise of signals obtained from the first sensor 205.

The filtering system 227 may comprise an analog filtering system including one or more hardware bandpass filters. The types of applicable hardware bandpass filters may include but not limited to Chebyshev filters, Butterworth filters, elliptic filters, LC filters and Bessel filters. The filter system 227 may comprise a digital filtering system including any one or more of the following types: Fast Fourier Transform (FFT) filters, Wiener filters, finite impulse response (FIR) filters, infinite impulse response (IIR) filters and Kalman filters. In the case where the filtering system 227 comprises a plurality of filters, the plurality of filters may be in series or in parallel. The digital filtering system can be achieved by programming using programming language, such as Python, C++, Java and Matlab.

Experimental evaluations were conducted to assess the applicability of detecting the field 207. FIG. 4 shows signals acquired from a 415 V front AC transmission powerline in a testing environment, where the frequency of the AC is 50 Hz. The measurement is conducted around 4 m below the overhead powerline 203. The results show a peak at 50 Hz that can be extracted by the filter system 227 and used to determine the presence of a 50 Hz signal. According to Walczak & Sikorski, signal strength is approximately directly proportional to source voltage and inversely proportional to the distance. That is, a response about 10 times stronger would be expected from a 4.15 kV powerline, and the electric field strength may decrease roughly linearly with the increase of distance.

### Second Sensor Configured to Detect a Relative Position

As shown in FIGS. 1 and 2, at step 120, the second sensor 209 detects a relative position 210 including a distance 211 between the overhead powerline (203) and the second sensor 209. In some embodiments, the distance 211 is the measurement of spatial separation from the centroid of the second sensor 209 to a point on the overhead powerline 203, which is closest to the centroid. In some embodiments, the relative position 210 further includes a direction of the overhead powerline 203, such as angular measurement in a spherical coordinate system including azimuth and altitude of the overhead powerline to the second sensor 209.

The second sensor 209 can include but not limited to the following types of sensors: a radar sensor, a LiDAR (laser imaging detection and ranging) sensor 214, and/or a camera sensor 216. Approaches for detecting 120 the relative position 210 are tailored to the type of the second sensor 209 employed. In some embodiments, a combination of more than one type of sensor (e.g., a combination of a LiDAR and camera sensors) is used synergistically as a second sensor 209 to enhance the sensing accuracy. This multi-sensor approach leverages the strengths of different types of sensors, enabling a more comprehensive and precise detection of the relative position.

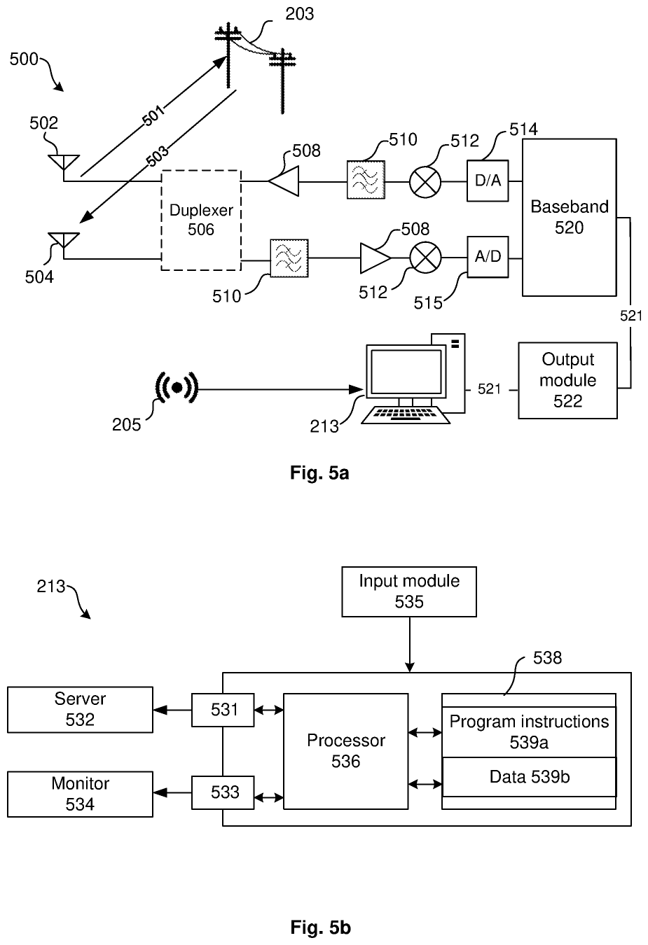

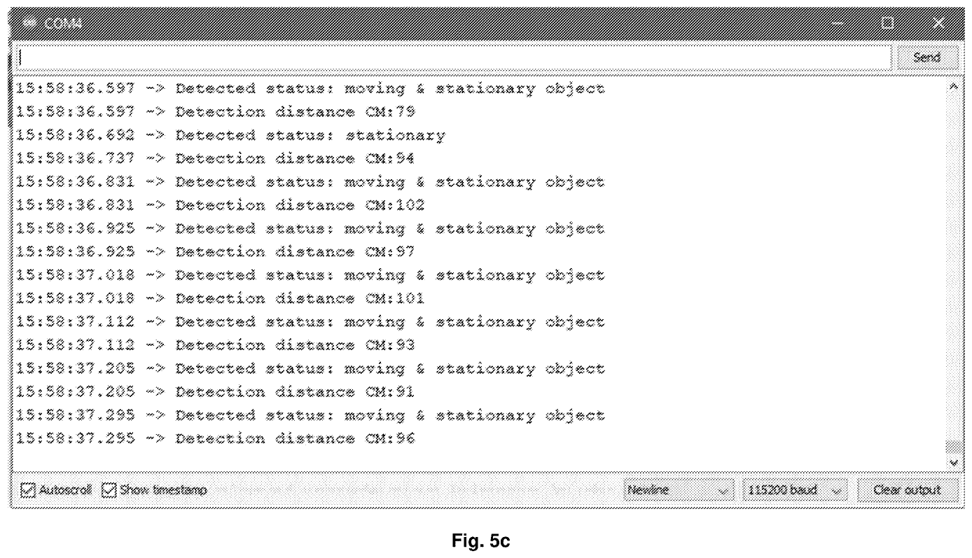

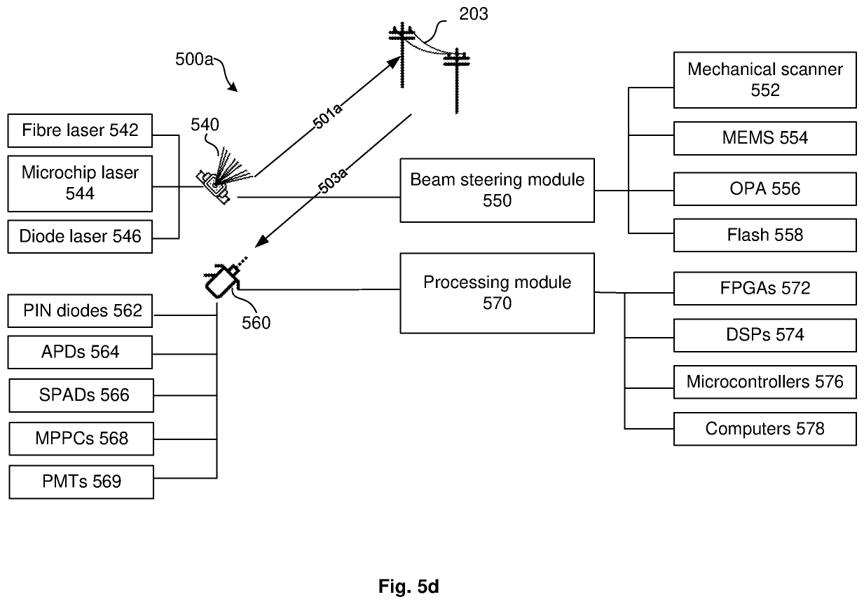

In some embodiments, the second sensor 209 comprises a radar sensor 500, as exemplified in FIG. 5a. The radar sensor 500 includes one or more transmitting antennas 502 configured to transmit signals to detect objects in the environment and one or more receiving antennas 504 configured to receive the signals reflected by the detected objects.

Typically, the radar antennas 502, 504 are directional antennas that concentrate the radiation power to certain directions. That is, antennas 502, 504 usually achieve a narrow beam width and high gain in desired directions to achieve effective detection of objects. The antennas 502, 504 can be any one of but not limited to the following types: array antennas (e.g., phased array antennas) including a plurality of antenna elements (e.g., microstrip antenna elements), horn antennas and parabolic antennas.

In some embodiment, the transmitting one or more antennas 502 can be the same as the receiving one or more antennas 504, that is, the transmitter and receiver sharing common antenna(s). In such embodiments, a duplexer 506 (e.g., a transmit-receive switch or a circulator) is often used for isolating the receiver from the transmitter while allowing them to share common one or more antennas 502, 504.

In some embodiments, signals implementing pre-designed radar waveforms (e.g., pulse waveforms, frequency-modulated continuous wave (FMCW) waveforms or linear frequency modulation waveforms) are generated at baseband 520 and transmitted to one or more digital-to-analog (D/A) converters 514 that convert digital signals to analog signals. The converted analog signals are then input to a frequency mixer 512 including a local oscillator. The frequency mixer 512 output signals of the frequency of the radar sensor 500 (which is typically higher than that of input signals in a transmitter).

The signals may then pass through one or more bandpass filters 510 configured to further extract signals of the desired frequency band and one or more amplifiers 508 (e.g., power amplifiers and/or low-noise amplifiers) configured to amplify the strength of the signal. The amplified and filtered radar signals are then transmitted by one or more antennas 502 to detect objects (e.g., overhead powerline 203).

Signals transmitted 501 from the one or more antennas 502 will be reflected by the detected object (e.g., the overhead powerline 203) and received 503 by one or more antennas 504. Similar to a “reversed” transmitting process, the received signals may pass through one or more bandpass filters 510 and one or more amplifiers 508. The amplified and filtered signals can be input into a frequency mixer 512 configured to output signals in a lower frequency band. The signals may then be converted to digital signals by the analog-to-digital converter (A/D) for further processing.

In some embodiments, digital signals in baseband 520 may be transmitted to controller 213 as second sensor data 219 through an output module 522 via a data flow 521. The controller 213 may further be connected to controller the first sensor 215. The first sensor data 217 and second sensor data 219 are fused and further processed by the controller 213.

Similar to underground wire detection using ground penetrating radar, the radar sensor 500 may operate in the centimetre wave frequency band (i.e., 3 GHz to 30 GHz). Alternatively, the radar sensor 500 may operate in the millimetre wave (mmWave) frequency band (i.e., 30 GHz to 300 GHz). The frequency of radar sensor 500 radar sensor 500 using mmWave is typically 24 GHz, 60 GHz or 77 GHz.

Advantageously, mmWave radars enable multi-object tracking sensing and the detection of objects of any shape, while experiencing minimal interference from other signals (e.g., the cellular, Wi-Fi or Bluetooth signals). Further, mmWave radars demonstrate robust performance in various atmospheric conditions (e.g., dust, smoke or fog) and light conditions (e.g., bright lights, dazzling lights or darkness). This robustness ensures consistent and reliable sensing in dynamic environments. Moreover, mmWave radars allow for the miniaturization of antennas and other microwave components, providing a compact profile of the radar sensor 500.

FIG. 5c illustrates test results for detected status and distances when aiming a sample radar sensor 500 (specifically, the DFRobot SEN0557 24 GHz radar) from a distance of about 1 m to a powerline. The test results show the applicability of using mmWave radar sensor 500 to detect overhead powerline 203. It should be understood that more advanced radar sensors can be applied to achieve comprehensive overhead powerline detection functions.

Based on radar principles, the distance 211 can be calculated based on a time of flight (also known as runtime) t of a radar signal, i.e., from the moment when the radar signal is transmitted by antenna 502 to the moment when the reflected radar signal is received by the receiver. The time of flight t may be measured by an oscilloscope. Accordingly, under ideal conditions (e.g., the radar signals are transmitted in the speed of light c in free space), the distance is calculated as

$$R = \frac{c \cdot t}{2} ,$$

where c equals to 3×10⁸ m/s. Different radar range equations (or other time of flight) can be used based on practical scenarios.

The relative position 210 may further include the direction of an object (e.g., a overhead powerline 203). To detect the direction, the radiation direction of the transmitting antenna(s) 502 may be continuously changed either by physically moving the transmitting antenna(s) 502, or by designing scanning radiation beams using beamforming techniques. The reflected signal strength varies as the antenna beam scans across the object (e.g., the overhead powerline 203). Specifically, the received reflected signal is of maximum strength (e.g., in amplitude), where the transmitted radar beam points to the object, indicating that the radiation direction of the radar beam aligns with the direction of the object. Such maximum-strength signals can be determined manually, by detection circuitry (e.g., automatic tracking circuits) or by advanced direction-of-arrival (DOA) estimation techniques implementing numerical optimisation approaches when the antennas 502, 504 are array antennas. Typically, the relevant position 210 is defined in a spherical coordinate system specifying azimuth and altitude (also known as an elevation angle) of the detected object.

In some embodiments, the radar sensor 500 further detects movements of the object, for example, when the overhead powerline 203 is in windy conditions or when there are other engineering vehicles in motion. The detection of the movement and estimation of the velocity of the detected object is based on the Doppler effect. Specifically, the Doppler frequency

$${f}_{d} \approx 2 {v}_{o} \frac{{f}_{t}}{c} ,$$

where vₒ is the velocity of the moving object and fₜ is the original frequency of the radar sensor 500. Detecting movements involves the measurement of the frequency of the reflected signal.

In some embodiments, the second sensor 209 is a LiDAR sensor transmitting laser signals. The fundamental principle for detecting the relative position 210, including the distance 211, using the LiDAR sensor is similar to the principle using the radar sensor 500. Specifically, like the radar sensor 500, the LiDAR sensor measures the time it takes for a Laser signal to travel to an object and be reflected back using light waves (instead of radio waves), such as wavelengths from the infrared and near-infrared regions. In other examples, wavelengths can also be selected from the visible or ultraviolet spectrums. Different forms of LiDAR equations may be employed to derive the relative position 210 based on the application scenario.

In some examples, the second sensor 209 is a LiDAR sensor 500a, as exemplified in FIG. 5d. The LiDAR sensor 500a includes but is not limited to a transmitter (also known as a light source or a source) 540, a beam steering module 550, a receiver (also known as a photodetector system) 560, and a processing module 570.

The transmitter 540 is configured to emit laser signals to detect objects in the environment. Typically, the transmitter 540 can be but not limited to any of the following types: i) a fibre laser 542 typically based on doped optical fibre (e.g., a 1550 nm fibre laser); ii) a microchip laser 544 (such as a bulk stainless steel (SS) laser with a piece of doped crystal or glass working as the gain medium); and iii) a diode laser 546, such as an interband laser and a quantum cascade laser (QCL).

In some embodiments, the transmitter/source 540 is connected to the beam steering module 550 for re-positioning the laser spot on the target by modifying the angular direction of the emitted laser beams that scan objects in the environment. The beam steering module 550 can be but not limited to any of the following types: i) a mechanical scanner 552 that uses use rotating mirrors and galvanometric or piezoelectric positioning of mirrors and prisms to perform the scanning; ii) a micro-electromechanical system (MEMS) scanner 554 that uses micromirrors, the tilt angle of each micromirror being controlled by applying a stimulus (e.g., voltage, electromagnetic actuation, or piezoelectric actuation), to generate scanning beams; iii) an optical phased array (OPA) scanner 556, which uses optical antennas to steer beam(s) based on beamforming principles; and iv) flash module 558 configured to illuminate the field of view by directing a single light pulse in an expanded range of directions.

The LiDAR sensor 500a also includes the receiver 560 configured to receive/detect the laser signals emitted from the transmitter 540 and reflected by the objects in the environment. The receiver 560 includes but not limited to any of the following types of photodetectors: i) P doped-Insulator-N doped (PIN) diodes 562; ii) avalanche photodiodes (APDs) 564; iii) single-photon avalanche photodiodes (SPADs) 566; iv) multi-pixel photon counters (MPPCs) 568; and v) photomultiplier tubes (PMTs) 569.

In some examples, the receiver 560 is connected to a processing module 570 including one or more processors. The processing module 570 typically collects and processes raw data received from the receiver 560, manages the operation of the LiDAR sensor, calculates desired parameters (e.g., the distance 215) and outputs sensing results (e.g., a LiDAR point cloud) based on signal processing algorithms. Depending on the system architecture, the processing module 570 often includes any one or more of the following types including: field programmable gate arrays (FPGAs) 572, digital signal processors (DSPs) 574, microcontrollers 576, and/or computers 578.

Using a LiDAR sensor as the second sensor brings a range of benefits. First, a LiDAR sensor provides high sensing accuracy (e.g., measurement of distances, shape and size), particularly in short ranges. Further, a LiDAR sensor can work in low-light environments with limited visibility. Moreover, a LiDAR sensor can output comprehensive 3D models of objects and environments. Additionally, a LiDAR sensor can collect data from a wide range of sources and automate large portions of work.

In some examples, the second sensor 209 further comprises a camera sensor 216. The camera sensor 216 is configured to capture visual data 218 of one or more objects in a surrounding environment, such as the overhead powerline 203, trees, utility poles, barricades, fencing and roofs. The camera sensor 216 may capture various types of visual data 218, such as still images, video sequences and 3D depth data (when the camera sensor 216 includes a depth camera).

In the cases where the second sensor 209 comprises the camera sensor 216, the controller 213 is further configured to process the visual data 218 of the one or more objects, including image recognition, tracking and processing. For example, the overhead powerline 203 can be recognised by pattern recognition of the images captured by the camera sensor 216. In some embodiments, relative position, which includes the distance 211 between the camera sensor 216 and an object, can be determined by the controller 213, for example, by employing the principle of triangle similarity, where the position of a reference point is known.

In some embodiments, the controller uses machine learning to detect the overhead powerline 203. Specifically, upon receiving the visual data 218 from the camera sensor 216, the controller 213 utilises a pre-trained machine learning model, such as a convolutional neural network (CNN) or a deep learning framework, to identify patterns and features specific to overhead powerlines 203, including a shape and/or distance 211 of the overhead powerline 203. Various image detection algorithms may be used, including two-stage object detection algorithms (e.g., Mask R-CNN, Pyramid Networks/FPN and G-RCNN) and one-stage object detection algorithms (e.g., You Only Look Once (YOLO) and Single Shot Detection (SSD)).

The machine learning model is trained on a dataset containing various images of overhead powerlines under different conditions, such as varying light, weather, and background environments, ensuring robustness and accuracy in real-world applications. The dataset can either be based on publicly available large datasets or custom datasets further tailored to specific application scenarios (e.g., work sites).

The controller 213 processes visual data 218 in real-time or near-real-time, determining the one or more objects including the overhead powerline 203. The determination process based on machine learning may include: extracting features from the visual data 218, comparing the extracted features to those in the machine learning model, and detecting and classifying the one or more objects in the visual data 218, which includes the overhead powerline 203. The determination process may also incorporate feedback to enhance accuracy over time, enabling the model to adapt to new conditions and improve recognition performance.

In some embodiments, the second sensor 209 includes both the LiDAR sensor 214 and the camera sensor 216. In such cases, determining the distance 211 of the overhead powerline 203 to the system comprises data fusion of the visual data 218 from the camera sensor 216 and distance data received from the LiDAR sensor 214. The data fusion may include comparing the distance 211 detected by the LiDAR sensor 214 and calculated from image processing, respectively, thereby cross-validating and refining the distance measurements. The data fusion allows the system to detect and track the powerline with increased accuracy, even in challenging conditions such as low light or complex backgrounds.

In some embodiments, GPS technology is employed to further assist the detection of relative position 210. For example, a rough relative position 210 may be initially estimated by a GPS sensor and further refined through the use of other sensors, such as the radar sensor 500.

In some embodiments, based on the second sensor data 219, the controller 213 is further configured to calculate one or more spatial boundaries in the surrounding environment, such as utility poles, barricades, fencing and roofs, to identify and delineate various physical structures. These spatial boundaries can be calculated by processing radar or LiDAR signals, or by conducting object detection based on the visual data 218 captured by the camera sensor 216.

To process the radar or LiDAR signals, the controller 213 may apply signal processing algorithms to generate a three-dimensional point cloud of the surrounding environment based on return signal strength, DOA, and time-of-flight measurements. The point cloud data can then be analysed to identify geometric patterns indicative of physical structures and determine boundary lines, distances, and relative positions.

Processing the visual data 218 captured by the camera sensor 216 to recognise the spatial boundaries is similar to recognising the overhead powerline 203 based on object detection, as described earlier. For example, one or more machine learning models can be used to detect different objects (e.g., utility poles, barricades, fencing and roofs) in the surrounding environment.

Based on the second sensor data 219, the controller 213 can be further configured to calculate one or more movements of the overhead powerline 203. The calculation can be based on the Doppler effect (where the second sensor 209 includes a radar and/or LiDAR sensor), or analysing visual data 218 of the overhead powerline 203 to detect position changes of the overhead powerline 203 over time. This further enhances situational awareness and operational safety, especially in complex and dynamic environments (e.g., work sites).

### Controller

FIG. 5b illustrates a block diagram of an exemplary configuration of a controller 213. The controller 213 comprises one or more processors 536 connected to a memory 538 configured to store program instructions 539a and data 539b. The memory 538 is a computer-readable medium, such as a hard drive, a solid state disk or CD-ROM. An executable computer program, embodied by instructions 539a, stored on memory 538 causes the one or more processors 536 to perform operations for receiving 130 sensor data from an input module 535, estimating 140 a live voltage value 221, determining 150 one or more threshold safety distances 223, generating 170 a warning signal 225 and other operations. In some embodiments, the input module 535 is connected to the output module 310 of the first sensor 205 and the output module 522 of the second sensor 209 via either wired data transmission components or wireless data transmission using radio frequency.

The memory 538 is configured to exchange data with the one or more processors 536 and may store the historical sensing data and information in relation to the sensors, the engineering vehicle and/or work site. The one or more processors 536 may generate and store the first sensor data 217 and the second sensor data 219 received from the first sensor 205 and the second sensor 209 as data 539b, such as within RAM or a processor register of the memory 538. The data 539b may further include data of the detected relative position 210 including the distances 211,215, the estimated live voltage value 221 and the one or more threshold safety distances 223.

The one or more processors 536 may receive data through different interfaces, including from an access to one or more parts of memory 538, including volatile memory, such as cache or RAM, or non-volatile memory, such as an optical disk drive, hard disk drive, storage server or cloud storage. The controller computer system 213 may further be implemented within a cloud computing environment, such as a work site monitoring sever. In such cases, the one or more processors 536 may send the data via communication port 531 to a server, such as an internet server 533.

A monitor 534, in the form of a computing device including hardware and software components, is configured to present data generated by one or more analysis, estimation and/or prediction operations performed one or more processors 536 (e.g., to present a live voltage value estimation). The monitor 534 receives data via communication port 533 in relation to the real-time and/or historical overhead powerline detection results and then presents the information and warning signals 225 through images, sounds or videos.

### Live Voltage Value Estimation and Threshold Safety Distances Generation

At step 140, the controller 213 estimates the live voltage value 221 of the overhead powerline 203 based on the first sensor data 217 in relation to the filed 207 and the second sensor data 219 in relation to the relative position 210 including the distance 211. In some embodiments, the estimation leverages a proportional relationship between the live voltage U₁ of the overhead powerline 203 and the voltage U₂ measured by the first sensor 205, as verified in Walczak & Sikorski and discussed at Equation 1.

In some embodiments, for common overhead powerlines where voltage values are standardized, such as 415 V, 11 kV, 19 kV, 33 kV and 66 kV, the voltage ratio v (see Equation 1) can be pre-determined at varying distances using known voltage sources. For example, for an overhead powerline with known U₁, v at varying distances r can be derived

$$v = \frac{{U}_{1}}{{U}_{2}} ,$$

from where U₂ can be measured by the first sensor 205 (e.g., the capacitive probe 302). This pre-measurement approach allows for the establishment of a reference dataset (e.g., a lookup table), which correlates specific voltage ratios v with corresponding distances r for these standard voltage values for common overhead powerlines.

In some embodiments, the values of C₂, Rₛ, and C₁ (see Equation 2) in response to different distances r and environment conditions (e.g., humidity) are pre-determined. Accordingly, v in equation 1 can be calculated.

The measured voltage ratios v corresponding to varying distances r may be recorded and pre-stored as empirical data in the memory 538 of the controller 213 (e.g., as a reference dataset) for retrieval in the future.

In some embodiments where the first sensor 205 and the second sensor 209 are co-located, the distance r between the first sensor and the overhead powerline 203 approximately equals the distance 211 between the overhead powerline 203 and the second sensor 209. In alternative embodiments where the first sensor 205 and the second sensor 209 are not co-located, the distance r between the first sensor 205 and the powerline 203 may be calculated (e.g., by vector addition in 3D space) based on the relevant positions of the first and second sensors on the engineering vehicle, and the relative position 210 of the overhead powerline 203 detected by the second sensor 209 (including the distance 211 between the overhead powerline 203 and the second sensor 209).

Upon obtaining the distance r from the relative position 210 detected by the second sensor 209, the voltage ratio v corresponding to r can be retrieved from the empirical data. The live voltage value 221 can then be derived by v times U₂, i.e., U₁=U₂·v, where U₂ can be obtained from the intensity of the field 207 detected by the first sensor 205. In one embodiment where the first sensor 205 is a capacitive sensor, U₂ can be measured by the capacitive probe 302.

In some embodiments, based on the relationship of variables shown in FIGS. 13 and 14 of Walczak & Sikorski, a linear relationship between U₁, U₂ and r can be derived as U₂=kU₁/r, where k is a constant for a specific distance r. The parameter k can be determined via a calibration process using a known voltage source and pre-stored in the memory 538 of the controller 213. When in operation, the live voltage value 221 can then be derived as U₁=U₂r/k, where U₂ can be measured by the first sensor 205 (e.g., the capacitive probe 302).

The one or more threshold safety distances 223 generated by the controller 223 is based on the live voltage value 221 and demarcates the danger zone 224 around the overhead powerline 203. In some embodiments, the generated one or more threshold safety distances 223 increase in response to an increase in the live voltage value 221. For example, a typical threshold radius 226 versus the live voltage value 221 is explicated in Table 1.

TABLE 1
Live voltage value 221 versus threshold radius 226 in one example.

| Live voltage value 221 (V) | Threshold radius 226 |
|---|---|
| More than 33,000 V | At least 6 m |
| 1000 V to 33,000 V | At least 3 m |
| 0 V to 1,000 V | At least 1 m |

In some embodiments, different threshold safety distances 223 segment areas associated with varying levels of risk associated with overhead powerline accidents. For example, as depicted in FIG. 2, the region between a larger virtual sphere with a threshold radius 226a and a smaller virtual sphere with a threshold radius 226b may be classified as a high-risk zone, while the area within the smaller virtual sphere having the threshold radius 226b may be considered as an extremely high-risk zone.

The threshold safety distance 223 may vary across different parts of the engineering vehicle where the system 200 attaches. For example, in the case where the engineering vehicle is an excavator, the threshold safety distance 223 set for the system 200 attached near a bucket of the excavator may differ from the threshold safety distance 223 set for the system 200 attached near a boom. This enables accurate hazard prediction and monitoring for engineering vehicles having complex structures and various operational states.

The tailored one or more threshold safety distances 223 enable the generation of different types of warning signals and, accordingly, allow the operator of the engineering vehicle to respond appropriately to different levels of hazard. As a result, the one or more threshold safety distances 223 enhance the overall effectiveness of the system 200 in safeguarding against potential risks of overhead powerline accidents.

It is to be appreciated that in some examples, the threshold safety distance(s) 223 is based on a distance extending from one or more reference points and the vehicle (where a powerline 203 within that safety distance is a safety risk). In alternative examples, the threshold safety distance 223 is the inversion of the above. That is, the threshold safety distance(s) 223 extends from one or more reference points of the overhead powerline. That is, if one or more parts of the vehicle enter withing the threshold safety distance surrounding the powerline, this will be a safety risk. In further examples, multiple threshold safety distances 223 can be used, including calculating a threshold safety distance from the hazard and a separate threshold safety distance from the vehicle (whereby intersection or overlap of the two safety distances will trigger a warning signal 225).

At step 160, the controller 213 determines 160 the distance 215 of the overhead powerline 203 to the system 200 based on the second sensor data 209. The distance 215 may be determined based on the relative position 210 detected by the second sensor 209, including the distance 211 and the direction information (such as azimuth and altitude of the overhead powerline to the second sensor 209). The distance 215 of the overhead powerline 203 and the system may be the measurement of spatial separation from the centroid of the system 200 to a point on the overhead powerline 203, which is closest to the centroid. In some embodiments, the system 200 is integrated where the first and second sensors 205,209 are co-located, the distance 215 approximately equals the distance 211 between the overhead powerline 203 and the second sensor 209.

### Warning Signal Generation

The controller 213 determines whether the system 200 is within or approaches the danger zone 224 demarcated by the one or more threshold safety distances 203. In some embodiments, the process is performed by a comparison module 212 that is configured to compare the value of the determined distance 215 with the values of the generated one or more threshold safety distances 223.

In response to determining that the distance 215 is within or approaches the one or more threshold safety distances 223, the controller 213 generates a warning signal 225 to remind the operator of the engineering vehicle of the potential hazard of overhead powerline accident.

In some embodiments, the controller 213 is configured to generate an emergency warning signal 228 in response to the first sensor data indicating the field being greater than or equal to the specified emergency threshold value 235. In one embodiment, the controller 213 generates the emergency warning signal 228 in response to the voltage U₂ measured by the first sensor 205 being greater than or equal to an emergency voltage threshold value Uₑ. Typically, the emergency warning signal is independent of the warning signal 225. In some examples, the emergency warning signal is presented by an emergency warning light, while the warning signals 225 correspond to different threshold safety distances 223 are presented by one or more threshold lights 732 different from the emergency warning light 734.

In some embodiments, in response to the first sensor data indicating the field being greater than or equal to the specified emergency threshold value (i.e., condition 235), the controller 213 bypasses the steps 140 to 170 to save computational resources. This is because, under such an extreme condition, the risk is considered high enough to directly establish an emergency status without the need to estimate the live voltage value 221 U₁ of the overhead powerline 203.

On the other hand, the controller 213 is configured to execute step 140, i.e., estimating the live voltage value 221, and the following steps 150 to 170, based on further condition 233 that the first sensor data 217 is less than the specified emergency threshold value. In one embodiment, the controller estimates 140 the live voltage value 221 in response to the voltage U₂ measured by the first sensor 205 being less than the emergency voltage threshold value Uₑ.

Advantageously, the approach streamlines the system's response time and reduces the computational load in critical situations, allowing the system to prioritise safety measures and respond efficiently to potential hazards.

In some embodiments, the controller 213 is configured to estimate the live voltage value 221 based on condition 231 that the first sensor data 217 is greater than or equal to a specified minimum threshold value. Under this condition, the risk is considered low, e.g., the engineering vehicle is considered sufficiently distant from the overhead powerline 203, thus eliminating the need to estimate 140 the live voltage value 221 and determine 150 the safety distance based on the live voltage value. In one example, the controller estimates 140 the live voltage value 221 in response to the voltage U₂ measured by the first sensor 205 being greater than or equal to the minimum voltage Um. This approach ensures that computational resources (e.g., those required for executing steps 140 to 170) are allocated according to necessity, optimising the efficiency of the system 200 while maintaining safety standards.

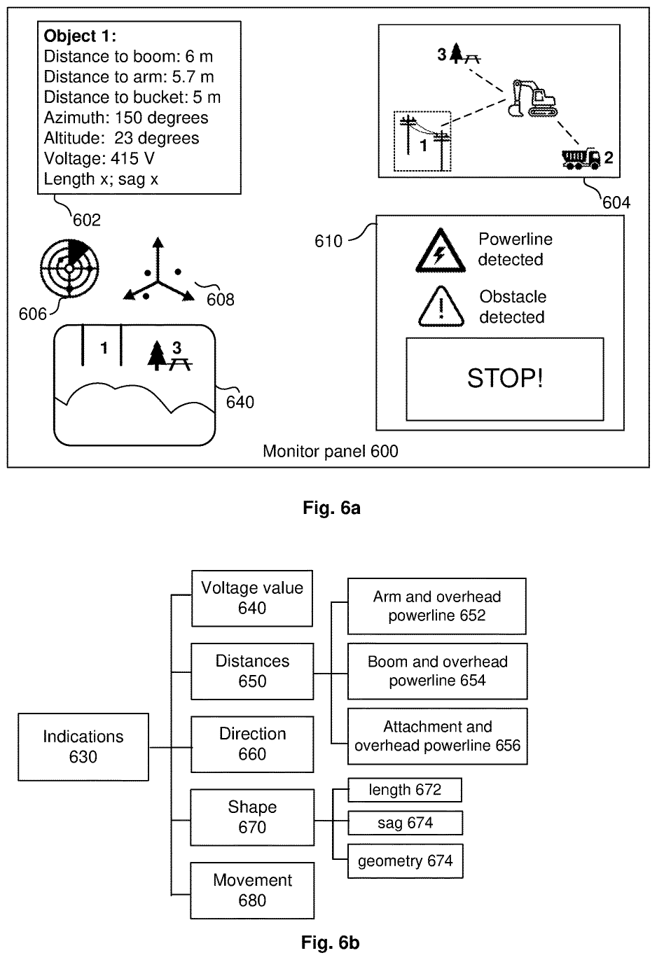

In some embodiments, a monitor panel 600 (see FIG. 6a) is configured to display an indication of a visual warning signal 720. This visual warning signal 720 may include a series of patterns, images, signs or literal contents corresponding to different types and levels of alert or operational status.

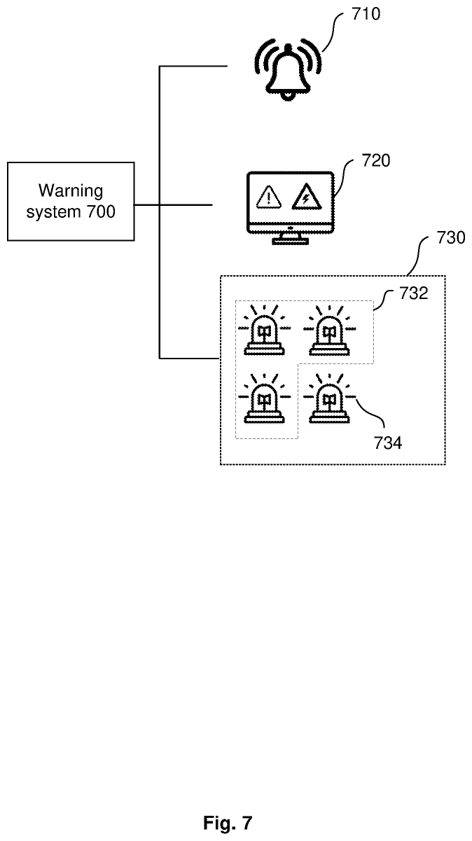

Referring to FIG. 7, the system 200 may further comprise a warning system 700 configured to deliver the warning signal 225 to the operator. The warning system 700 may comprise one or more alarm devices 710 configured to generate acoustic signals such as a warning buzzer/horn, alert siren and voice warning signals. Levels of risk can be distinguished by varying the type and/or volume of acoustic signals produced by the one or more alarm devices 710.

The warning system 700 may also comprise one or more warning lights 730. The one or more warning lights 730 includes one or more threshold lights 732 to present different levels of risk, and an emergency warning light 734 presenting the emergency warning signal requiring an immediate stop of the engineering vehicle. Distinct risk levels may be presented through variations in the colours and/or luminance of the warning lights 730. For example, there may be warning lights emitting green, yellow and red lights to denote the engineering vehicle being in safe, risky and emergency statuses, respectively.

The warning system 700 may further comprise one or more emergency shut-off mechanisms configured to stop one or more actuators of the engineering vehicle. The emergency shut-off mechanisms can be automatically triggered in response to a critical risk of powerline accidents, for example, in response to receiving the emergency warning signal. Stopping one or more actuators of the engineering vehicle can effectively halt the operation of key components, such as motors and moving parts (e.g., the boom of the engineering vehicle), to prevent accidents or further system damage.

The above different types of warning methods can be either implemented independently or in combination. The warning system 700 allows for flexible adaptation to a variety of operational scenarios and risk profiles. The integration of multiple warning methods can ensure that operators of the engineering vehicle receive timely and clear alerts, enabling quick and appropriate responses to potential hazards.

### Third Sensor

In some embodiments, the system 200 may further comprise a third sensor 229 configured to detect a proximity between the third sensor 229 and one or more objects in a surrounding environment (e.g., in the work site). The objects may include the overhead powerline 223 and other objects such as trees, buildings, other engineering vehicles, barricades, fencing, people and animals. That is, items that are in close proximity to the vehicle.

The third sensor 229 is typically a proximity sensor which can detect the presence of nearby objects without making physical contact with them. In response to the detected proximity is at or below a safety margin, the controller 213 is further configured to generate a further alarm to warn of a risk of collision between the one or more object and the system 200.

In some examples, ultrasonic sensors, inductive proximity sensors, capacitive proximity sensors, magnetic proximity sensors laser proximity sensors, and optical camera systems (including stereoscopic camera systems) may be used as the third sensor 229. Such sensors may be advantageous as they will detect objects that may not be actively carrying live current.

In some embodiments, the third sensor 229 cooperates with the warning system 700 to activate the generation of warning signals and trigger one or more emergency shut-off mechanisms. For example, in response to the third sensor 229 detecting a nearby object, the controller may further activate an emergency warning light and emergency acoustic signals and trigger an emergency braking of the engineering vehicle.

The third sensor 229 may function independently of the first and second sensors 205,209. Not limited to overhead powerline 203, the third sensor 209 provides additional protection against any type of physical objects in the environment. This may be useful for detecting (or as a supplement to detecting) other electrical systems such as DC systems. The third sensor 229 also serves as an effective failsafe, ensuring continuous protection in the event of failure or compromised functionality of the first and second sensors 205, 209.

### User Interface

FIG. 6a illustrates an exemplary user interface displayed on a monitor panel 600 of the system 200. Typically, the monitor panel 600 is positioned inside a cabin of the engineering vehicle, enabling the operator to have a comprehensive view of the engineering vehicle's parameter settings and the surrounding environment where the engineering vehicle operates.

In some embodiments, the monitor panel 600 is configured to display one or more indications 630 as exemplified in FIG. 6b. The indications 630 may comprise any one or more indications of distances 654, 654, 656 including: a second distance 652 between the arm of the engineering vehicle and the overhead powerline 203, a third distance 654 between the boom of the engineering vehicle and the overhead powerline 203, and a fourth distance 656 between the attachment of the engineering vehicle and the overhead powerline 203. These indications of distances 654, 654, 656 may be shown in a parameter panel 602 as shown in FIG. 6a.

The indications 630 may also comprise an indication of the direction 660 of the overhead powerline 203. In some embodiments, the direction information is defined using the spherical coordinate system, providing values of the azimuth and altitude of the overhead powerline 203, as shown on the parameter panel 602. In some examples, the direction information can also be illustrated in a radar chart 606 showing the scanning range and a 3D-axis positioning chart 608, where the positions of objects in the detected environment are presented as distributed dots.

In some embodiments, the indications 630 further comprises an indication of the shape 670 of the overhead powerline 203. The shape 670 may include a length 672 and/or a sag 674 of the overhead powerline 203. In some examples, the shape 670 may further include a geometry 674 of the overhead powerline 203 which may be captured by a camera sensor or reconstructed from the second sensor data 219 using radar sensing, image processing and/or machine learning technologies.

In some embodiments, the monitor panel 600 is further configured to display indication 640 of the real-time or near-real-time visual data 218 of the overhead powerline 203 captured by the camera sensor 216. The image or partial image of the overhead powerline 203 may be shown in the indication 640 to assist the operator of the engineering vehicle in identifying the overhead powerline 203.

In some embodiments, the monitor panel 600 is further configured to display a point cloud of the surrounding environment generated by the LiDAR sensor 214 (not shown). The point cloud provides a three-dimensional representation of objects and surfaces within the environment, created from distance measurements collected by the LiDAR sensor 214 as it scans the area. Each point in the point cloud corresponds to a specific location in space, with coordinates and attributes, such as reflectivity, which may assist in distinguishing between different surfaces, objects, and environmental features. The monitor panel 600 may be further configured to render the point cloud data, offering a comprehensive and interactive visual of the surroundings.

Additionally, the monitor panel 600 may include a 3D view panel 604 displaying the simulated position relationships between the engineering vehicle and the sensed objects in the environment. In some embodiments, parameters presented in the parameter panel 602 can vary based on the selection of one of the detected objects on the 3D view panel 604.

The radar chart 606, 3D-axis positioning chart 608 and the 3D view panel 604 effectively illustrate the positions of objects in the surrounding environment, offering the operator of the engineering vehicle a clear and intuitive understanding of the spatial relationship between the engineering vehicle and surrounding obstacles including the overhead powerline 203. This can aid in increasing situational awareness.

The indications 630 may also comprise an indication of the movement 680 of the overhead powerline 203. For example, the movement may be shown on the 3D view panel 604 or shown as moving dots on the radar chart 606 and the 3D-axis positioning chart 608.

In response to determining that the system 200 is within or approaches the one or more threshold safety distances 223, the monitor panel 600 further displays an indication 610 of a visual warning signal 720. The indication 610 of visual warning signal 720 may be in the form of patterns, images, signs and literal contents corresponding to different types and levels of alert or operational statuses. Additionally, the indication 610 of the warning signal 720 can be programmed to change intensity or blink in specific patterns to draw attention to urgent issues.

### Configuration on an Engineering Vehicle

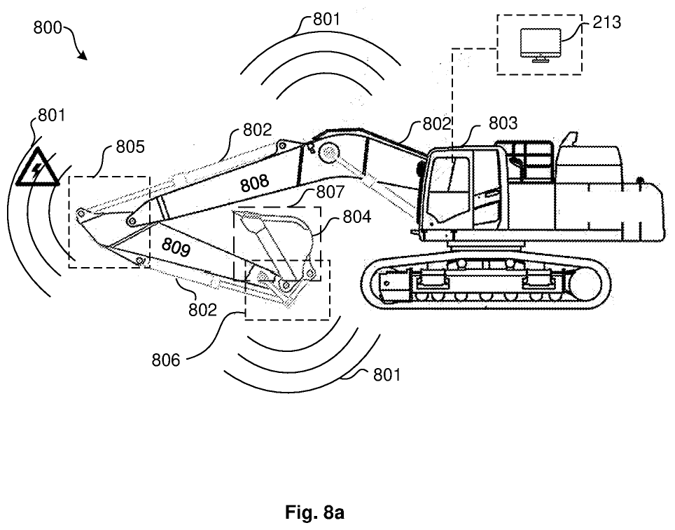

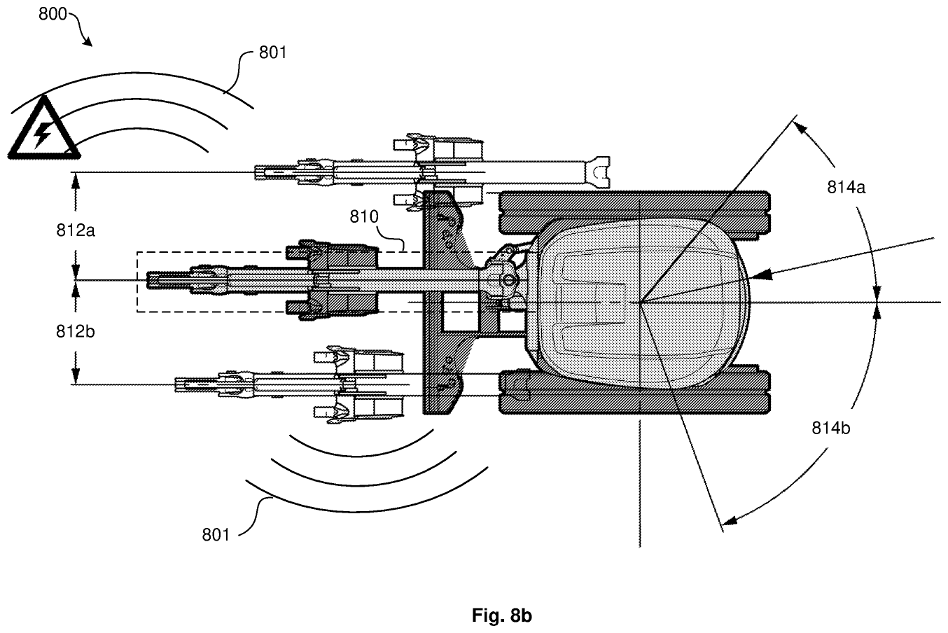

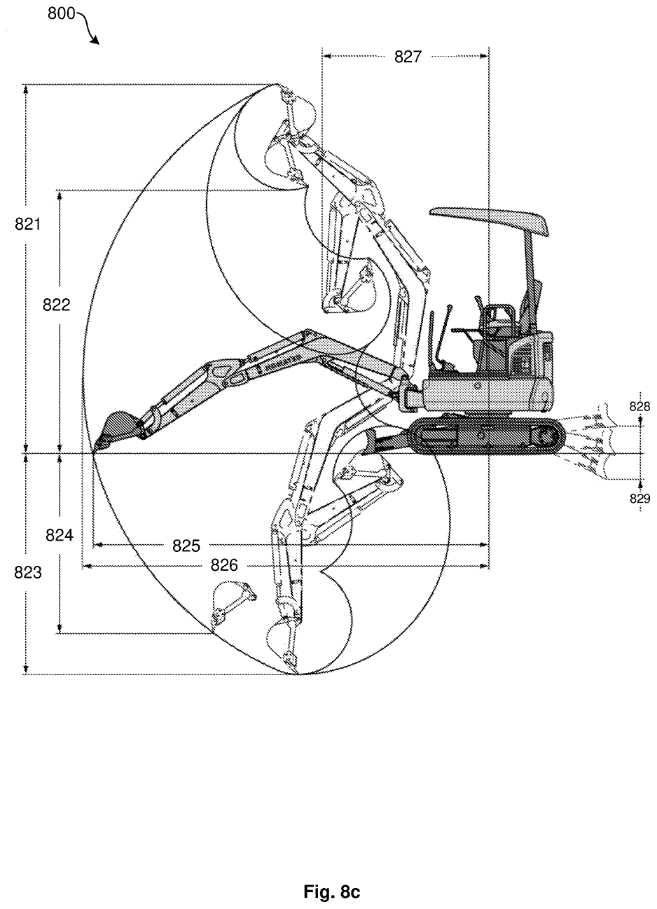

FIG. 8a illustrates an example of an engineering vehicle 200 using the system 200. It should be understood that while the system 200 is depicted as attached to an excavator in this example, the application scenarios for the system 200 are not limited to excavators alone. The system 200 is also adaptable for use with various other engineering vehicles, including but not limited to backhoes, electric rope shovels and dump trucks.

As shown in FIG. 8a, the first sensor 205, the second sensor 209 (e.g., the LiDAR sensor 214 and the camera 216), and the third sensor 229 (e.g., the proximity sensor) of system 200 may be located on one or more parts of the engineering vehicle 800 comprising an arm assembly 810, a cabin 803 and other parts. In some embodiments, the system 200 is associated with the arm assembly 810 of the engineering vehicle 800, including a boom 808, an arm 809 and an attachment 804 (e.g., such as a bucket). For example, at least one of the sensors 205,209,229 may be provided at respective sensor locations 805, 806, 807 on the arm assembly 810.

The respective sensor locations 805, 806, 807 may include any one or more of a location near a first joint of the boom 808 and the arm 809 of the engineering vehicle 800; a location near a second joint of the arm and the attachment 804 of the engineering vehicle 800; and/or a location on the attachment 804 of the engineering vehicle 800.

In some embodiments, the sensor locations are strategically selected to achieve a desired sensing range 810. It should be understood that the sensing range 810 depicted in FIGS. 8a and 8b are for illustration purposes only and are not intended to limit the actual sensing range in practical applications. This flexibility in sensor placement allows for customization according to specific operational needs and working environments, ensuring the desired detection range (e.g., providing small or negligible blind spots) of the system 200.

In some embodiments, different sensors are positioned at different sensor locations, such as sensor locations 805, 806, 807, to optimize performance based on sensor type. For example, the camera sensor 216 may be places at sensor locations 805 to maintain an unobstructed view, while the LiDAR sensor 214 may be positioned at sensor location 806 to achieve accurate estimate of the distance between the attachment 804 of the engineering vehicle 800 and the powerline 203.

In some embodiments, the sensors 205, 209, 229 are connected to the controller 213 inside the cabin 803 via wiring 802 (e.g., in the form of cables) to enable data transmission. In alternative embodiments, the sensors 205, 209, 229 are connected to the controller 213 via wireless data transmission using radio frequency (e.g., Wi-Fi, Bluetooth or Cellular Networks).

In some embodiments, the one or more threshold safety distances 223 are further based on a size and/or configuration of one or more components of the engineering vehicle associated with the system 200. When in operation, the sensors 205, 209, 229 and the components of the engineering vehicle may be in motion. By adapting the threshold safety distances 223 based on the size and/or configuration of these components, the system 200 can provide more efficient and accurate detection in dynamic practical environment.

The size and/or configuration may include an overall size and/or shape of the engineering vehicle; a length and/or height of a boom of the engineering vehicle; a length and/or height of an arm of the arm assembly; a reach of the engineering vehicle; a digging height of the engineering vehicle; a dumping height of the engineering vehicle (e.g., for a dump truck); a swing radius of the boom and/or the arm of the arm assembly; a swing radius of an attachment of the engineering vehicle, wherein the attachment is attached to a distal end of the arm assembly; one or more boom swing angles of the engineering vehicle; and a configuration, size and/or position of a cabin of the engineering vehicle.

Referring to FIGS. 8b and 8c, the below Table 2 presents typical configuration parameters of an engineering vehicle 800 (such as an excavator) that should be taken into account. The actual values of these parameters are dynamic and a plurality of these parameters will be used by the controller to calculate relative and/or absolute position of components (e.g. attachments, boom, arm, etc) of the engineering vehicle 800.

TABLE 2
Typical configuration parameters of an excavator.

| 812a | Bucket offset (Right) |
|---|---|
| 812b | Bucket offset (Left) |
| 814a | Boom swing angle (Right) |
| 814b | Boom swing angle (Left) |
| 821 | Maximum digging height |
| 822 | Maximum dumping height |
| 823 | Maximum digging depth |
| 824 | Maximum vertical digging depth |
| 825 | Maximum digging reach at ground level |
| 826 | Maximum digging reach |
| 827 | Minimum swing radius (when boom swing) |
| 828 | Maximum blade lift |
| 829 | Maximum blade depth |

It will be appreciated by persons skilled in the art that numerous variations and/or modifications may be made to the above-described embodiments, without departing from the broad general scope of the present disclosure. The present embodiments are, therefore, to be considered in all respects as illustrative and not restrictive.

1. A system for detecting an overhead powerline, the system comprising:
a first sensor configured to detect a field generated by the overhead powerline;
a second sensor configured to detect the overhead powerline, and a relative position, including a distance, between the overhead powerline and the second sensor, wherein the second sensor comprises a camera sensor configured to capture visual data of one or more objects in a surrounding environment; and
a controller including one or more processors configured to:
receive first sensor data from the first sensor and second sensor data from the second sensor;
determine the one or more objects in the surrounding environment including the overhead powerline based on the visual data;
estimate a live voltage value of the overhead powerline based on the first sensor data and the second sensor data;
determine one or more threshold safety distances based on the live voltage value;
determine the distance of the overhead powerline to the system based on the second sensor data; and
in response to the determined distance is within, or approaches, the one or more threshold safety distances, generate a warning signal.

2. The system of claim 1, wherein the controller is configured to generate an emergency warning signal in response to the first sensor data indicating the field being greater than or equal to the specified emergency threshold value.

3. The system of claim 1, further comprising a filtering system configured to extract, from the first sensor data, signals in a specified frequency band corresponding to the field generated at the overhead powerline by alternating current,
wherein the signals in the specified frequency band are indicative of live alternating current in the overhead powerline.

4. The system of claim 1, wherein the determined one or more threshold safety distances increase in response to an increase in the live voltage value.

5. The system of claim 1, wherein the controller is configured to estimate the live voltage value based on a condition that the first sensor data is greater than or equal to a specified minimum threshold value.

6. The system of claim 1, wherein the second sensor comprises any one or more of:
a Light Detection and Ranging sensor;
a combination of the LiDAR sensor and the camera sensor;
a combination of the LiDAR sensor and the camera sensor comprising a depth camera; or
a millimetre wave radar.

7-8. (canceled)

9. The system of claim 6, wherein determining the distance of the overhead powerline to the system comprises data fusion of the visual data from the camera sensor and distance data received from the LiDAR sensor.

10. The system of claim 1, wherein the system is associated with an engineering vehicle comprising an arm assembly, wherein at least one of the first sensor or the second sensor are provided at respective sensor locations on the arm assembly, wherein the respective sensor locations include any one or more of:
a location near a first joint of the boom and the arm of the engineering vehicle;
a location near a second joint of the arm and the attachment of the engineering vehicle; and/or
a location on the attachment of the engineering vehicle.

11. The system of claim 1, wherein the one or more threshold safety distances are further based on a size and/or configuration of one or more components of the engineering vehicle associated with the system,
wherein the size and/or configuration includes one or more of:
an overall size and/or shape of the engineering vehicle;
a length and/or height of a boom of the engineering vehicle;
a length and/or height of an arm of the arm assembly;
a reach of the engineering vehicle;
a digging height of the engineering vehicle;
a dumping height of the engineering vehicle;
a swing radius of the boom and/or the arm of the arm assembly;
a swing radius of an attachment of the engineering vehicle, wherein the attachment is attached to a distal end of the arm assembly;
one or more boom swing angles of the engineering vehicle; and
a configuration, size and/or position of a cabin of the engineering vehicle.

12. (canceled)

13. The system of claim 6, wherein based on the second sensor data, the controller is further configured to calculate any one or more of:
one or more spatial boundaries in the surrounding environment; and/or
one or more movements of the overhead powerline.

14-16. (canceled)

17. The system of claim 1, wherein the relative position further includes a direction of the overhead powerline.

18. The system of claim 10, wherein the system further comprises a third sensor configured to detect a proximity between the third sensor and the one or more objects in the surrounding environment, the objects including the overhead powerline,
wherein in response to the detected proximity is at or below a safety margin, the controller is further configured to generate a further alarm to warn of a risk of collision between the one or more object and the engineering vehicle.

19. The system of claim 1, wherein detecting the overhead powerline further comprises determining a shape extracted from the second sensor data that corresponds to one or more of a length of the overhead powerline, a sag of the overhead powerline, and/or a geometry of the overhead powerline.

20. The system of claim 19, wherein the system further comprises a monitor panel configured to display one or more indications including any one or more of:
an indication of the voltage value of the overhead powerline;
an indication of a second distance between the arm of the engineering vehicle and the overhead powerline;
an indication of a third distance between the boom of the engineering vehicle and the overhead powerline;
an indication of a fourth distance between the attachment of the engineering vehicle and the overhead powerline;
an indication of one or more directions of the overhead powerline and/or one or more directions of the one or more objects in the surrounding environment;
an indication of the shape of the overhead powerline;
an indication of the movement of the overhead powerline;
an indication of the real-time or near-real-time visual data of the surrounding environment;
an indication of a point cloud of the surrounding environment; and/or
an indication of a visual warning signal.

21. The system of claim 1, wherein the system further comprising a warning system, wherein the warning system comprises any one or more of:
one or more warning lights including one or more threshold lights and an emergency warning light configured to present the emergency warning signal;
one or more alarm devices; and
one or more emergency shut-off mechanisms configured to stop one or more actuators of the engineering vehicle.

22. The system of claim 2, wherein the filtering system comprises any one or more of:
an analog filtering system including a hardware bandpass filter; and/or
a digital filtering system including a Fast Fourier Transform filter.

23. The system of claim 1, wherein determining the one or more objects including the overhead powerline based on the visual data comprises applying a machine learning model, trained with previous visual datasets of overhead powerlines, to the visual data.

24. The system of claim 23, wherein applying the machine learning model to the visual data comprises identifying one or more features specific to the overhead powerline.

25. The system of claim 1, wherein detecting the relative position comprises processing the visual data based on a predetermined position of a reference point associated with the one or more objects in the surrounding environment.

26. A method for detecting an overhead powerline by a system comprising a first sensor, a second sensor and a controller including one or more processors, wherein the method comprises:
detecting, by a first sensor, a field generated by the overhead powerline;
detecting, by a second sensor, the overhead powerline, and a relative position, including a distance, between the overhead powerline and the second sensor, wherein the second sensor comprises a camera sensor configured to capture visual data of one or more objects in a surrounding environment;
receiving, by a controller including one or more processors, first sensing data from the first sensor and second sensing data from the second sensor;
determining the one or more objects in the surrounding environment including the overhead powerline based on the visual data;
estimating, by the controller, a live voltage value of the overhead powerline using the first sensing data and the second sensing data;
determining, by the controller, one or more threshold safety distances based on the live voltage value; and
determining, by the controller, the distance of the overhead powerline to the system based on the second sensor data,
in response to the determined distance is within, or approaches, the one or more threshold safety distances, generate a warning signal.

27. (canceled)
